(19) United States
(12) Patent Application Publication
(10) Pub. No.: US 2019/0006531 A1
(43) Pub. Date: Jan. 3, 2019

(54) CISCSP Package and Related Methods

(71) Applicant: SEMICONDUCTOR COMPONENTS INDUSTRIES, LLC, Phoenix, AZ (US)

(72) Inventor: Shou-Chian HSU, Zhubei City (TW)

(73) Assignee: SEMICONDUCTOR COMPONENTS INDUSTRIES, LLC, Phoenix, AZ (US)

(21) Appl. No.: 15/939,582

(22) Filed: Mar. 29, 2018

Related U.S. Application Data
(60) Provisional application No. 62/527,787, filed on Jun. 30, 2017.

(51) Int. Cl. H01L 31/02; H01L 27/146

(52) U.S. Cl. CPC H01L 31/02005; H01L 27/14616; H01L 27/14643

(57) ABSTRACT

Implementations of semiconductor packages may include: a semiconductor die including a plurality of pads and a first dielectric layer with a plurality of openings therethrough that expose at least a portion of each of the plurality of pads. A second dielectric layer coupled to the first dielectric layer may have a thickness greater than or equal to a thickness of the first dielectric layer and a plurality of openings corresponding with the plurality of openings in the first dielectric layer. A plurality of bumps may be coupled with the plurality of pads into the plurality of openings in the first dielectric layer and in the second dielectric layer. The semiconductor package may also include a bump encapsulation material extending upwardly from the material of the plurality of pads along sides of the plurality of bumps. The package may couple with a motherboard using no underfill material.

### CROSS REFERENCE TO RELATED APPLICATIONS

This document claims the benefit of the filing date of U.S. Provisional Patent Application 62/527,787, entitled “CISCSP Package and Related Methods” to Shou-Chian Hsu which was filed on Jun. 30, 2017, the disclosure of which is hereby incorporated entirely herein by reference.

### BACKGROUND

### 1. Technical Field

Aspects of this document relate generally to image sensors. More specific implementations involve image sensor packages designed to couple to motherboards.

### 2. Background

Generally, to couple a semiconductor packages to a motherboard, underfill material is often used to fill the space in between bumps on the package and the motherboard. In some systems, a polymer or other material is initially distributed around the bumps on the semiconductor package either prior to or after it is coupled with the motherboard and the underfill material applied and cured. The use of the underfill material is used to prevent cracking of the bump near the point of connection with the motherboard or cracking of the redistribution layer (RDL) circuitry during thermal cycling of the package

### SUMMARY

Implementations of semiconductor packages may include: a semiconductor die including a plurality of pads and a first dielectric layer with a plurality of openings therethrough that expose at least a portion of each of the plurality of pads. The semiconductor packages may also include a second dielectric layer coupled to the first dielectric layer. The second dielectric layer may have a plurality of openings corresponding with the plurality of openings in the first dielectric layer. The plurality of openings of the second dielectric layer may have a width that is greater than a width of the plurality of openings of the first dielectric layer. The semiconductor package may also include a plurality of bumps coupled with the plurality of pads into the plurality of openings in the first dielectric layer and into the plurality of openings in the second dielectric layer. The semiconductor package may also include a bump encapsulation material disposed around the plurality of bumps and extending upwardly from the material of the plurality of pads along sides of the plurality of bumps. The package may be configured to couple with a motherboard using no underfill material between the plurality of bumps and the motherboard.

Implementations of semiconductor packages may include one, all, or any of the following:

The second dielectric layer may have a thickness greater than or equal to a thickness of the first dielectric layer.

A material of the first dielectric layer may be one of the same as and different from a material of the second dielectric layer.

The thickness of the second dielectric layer may be configured to raise the encapsulation height of a solder encapsulation material to a desired height.

The thickness of the second dielectric layer may be greater than 30 microns.

The semiconductor die may be an image sensor including a plurality of microlenses coupled to the semiconductor die. A dam may be coupled around a perimeter of the semiconductor die. A glass layer may be coupled to the dam over the semiconductor die.

The first dielectric layer and the second dielectric layer may each be applied using one of spray coating, spin coating, and lamination.

Implementations of complementary metal oxide semiconductor (CMOS) image sensor chip scale packages (CISCSP) may include: a semiconductor die having a plurality of pads and a first solder mask defined (SMD) layer with a plurality of openings therethrough. The openings through the first solder mask may expose at least a portion of each of the plurality of pads. The package may also include a second non-solder mask defined (NSMD) layer coupled to the first SMD layer. The second NSMD layer may have a plurality of openings corresponding with the plurality of openings in the first SMD layer. The plurality of openings of the second NSMD layer may have a width that is greater than a width of the plurality of openings of the first SMD layer. The package may have a plurality of bumps coupled with the plurality of pads into the plurality of openings in the first SMD layer and into the plurality of openings in the second NSMD layer. The package may have a bump encapsulation material disposed around the plurality of bumps and extending upwardly from the material of the plurality of pads along sides of the plurality of bumps.

Implementations of CISCSPs may include one, all, or any of the following:

A material of the first SMD layer may be one of the same as and different from a material of the second NSMD layer.

The first SMD layer may include a film.

The second NSMD layer may include a film.

The thickness of the second NSMD layer may be configured to raise the encapsulation height of a solder encapsulation material to a desired height.

The thickness of the second NSMD layer may be greater than 30 microns.

The package may further include a plurality of microlenses coupled to the semiconductor die. A dam may be coupled around a perimeter of the semiconductor die. A glass layer may be coupled to the dam over the semiconductor die.

The first dielectric layer and the second dielectric layer may be applied using one of spray coating, spin coating, and lamination.

Implementations of a method of forming a complementary metal oxide semiconductor (CMOS) image sensor chip scale package (CISCSP), may include: providing a semiconductor layer having a plurality of pads thereon; applying a first dielectric layer to the semiconductor layer; and forming a plurality of openings in the first dielectric layer over the plurality of pads. The method may also include applying a second dielectric layer to the semiconductor layer and forming a plurality of openings in the second dielectric layer corresponding with the openings in the first dielectric layer. The method may include applying a ball encapsulation material to the plurality of pads; dropping a plurality of balls into the ball encapsulation material; reflowing the plurality of balls to couple the plurality of balls with the plurality of pads; and curing the ball encapsulation material along sides of the plurality of balls, the ball encapsulation material height along the sides determined by a thickness of the second dielectric layer. The thickness of the second dielectric layer may be configured to raise a height of the ball encapsulation of a solder encapsulation material to a desired height. The thickness of the second dielectric layer may be greater than 30 microns.

Implementations of a method of forming CISCSPs may include one, all, or any of the following:

A material of the first dielectric layer may be one of the same material and a different material from a material of the second dielectric layer.

The second dielectric layer may have a thickness that is one or equal to or greater than a thickness of the first dielectric layer The method may also include coupling a plurality of microlenses to the first side of the semiconductor layer, coupling a dam around a perimeter of the semiconductor layer, and coupling a glass layer to the dam over the semiconductor layer.

The first dielectric layer and the second dielectric layer may be applied using spray coating, spin coating, or lamination.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1A is a scanning electron microscope (SEM) image of a solder neck crack in a bump not encapsulated in underfill;

FIG. 1B is a SEM image of a crack in the RDL circuitry;

FIG. 2A is a cross sectional view of a CISCSP;

FIG. 2B is a cross sectional view of a wafer level chip scale package;

FIG. 3 is a cross sectional view of a CISCSP of FIG. 2A coupled to a motherboard using underfill material;

FIG. 4A-4D is a process flow of a method of forming a semiconductor package;

FIG. 5A-5E is a process flow of an implementation of a method of forming a semiconductor package having two layers of dielectric layers;

FIG. 6A is a cross sectional views of an implementation of a semiconductor package having two layers of dielectric layers;

FIG. 6B is a close up view of an implementation of a bump as described herein; and

FIG. 6C is a bottom view of an implementation of a semiconductor package disclosed herein.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

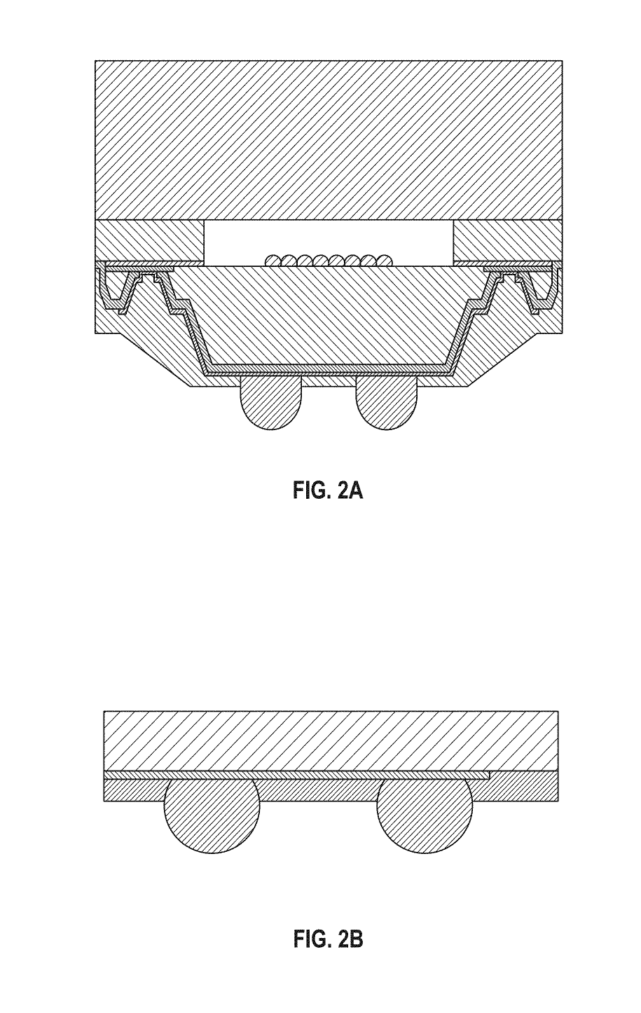

When coupling a semiconductor package to a motherboard, an underfill material may be used to fill the space in between the bumps and the motherboard as illustrated in FIG. 2A. A polymer or other material may be initially distributed around the bumps on the semiconductor package before it is coupled with the motherboard and the underfill material applied and cured. This technique is referred to as a “polymer collar” or a joint protection paste.

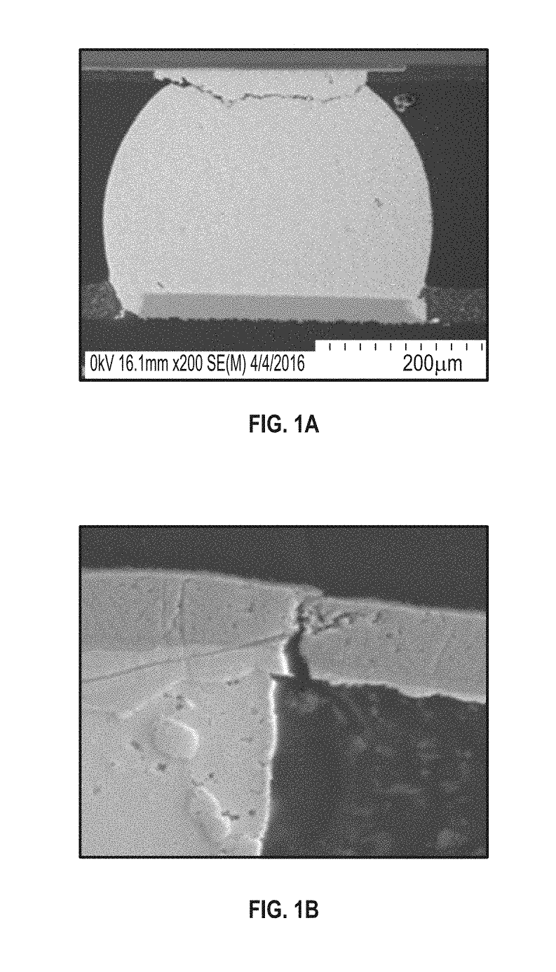

Underfill material may also be used to prevent cracking of the bump near the point of connection with the motherboard or cracking of the redistribution layer (RDL) circuitry. This cracking occurs because of the thermal stresses created by the coefficient of thermal expansion (CTE) mismatches between the materials of the assembled CISCSP package and the motherboard during operation and thermal cycling. FIG. 1A illustrates a solder neck crack in a bump not encapsulated in underfill due to the CTE mismatch stress and FIG. 1B illustrates a crack in the RDL circuitry that results from the same issue.

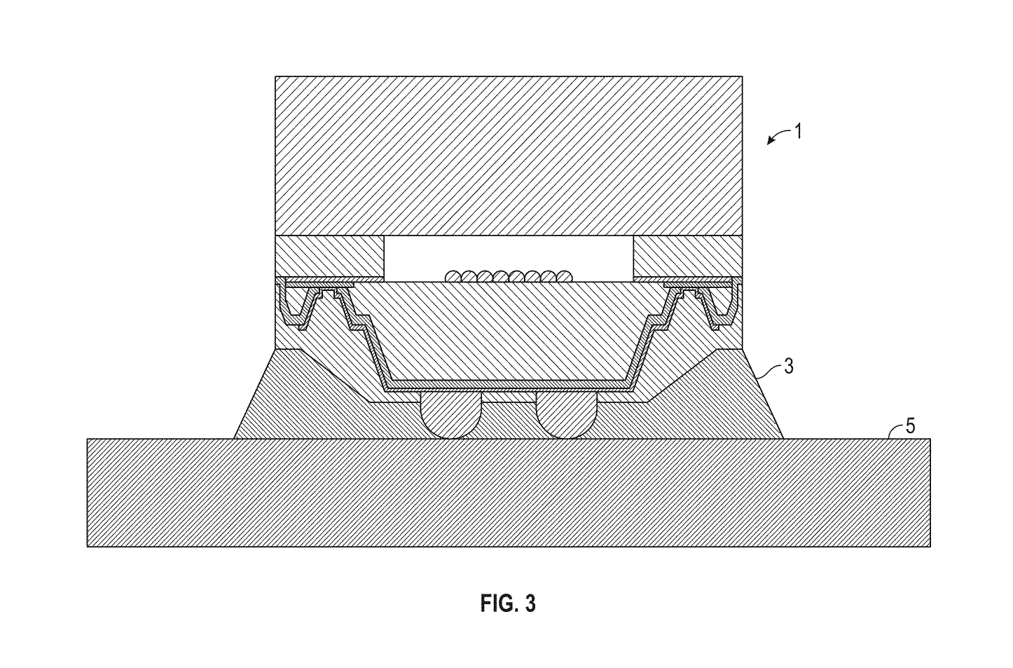

The stresses in the die may occur in both complementary metal oxide semiconductor (CMOS) image sensor chip scale packages (CISCSP) and in wafer level chip scale packages (WLCSP), but may be particularly acute in CISCSP designs due to the structural differences in the materials and shape of a CISCSP. An example of a CISCSP is illustrated in FIG. 2A and an example of a WLCSP is found in FIG. 2B. An example of a CISCSP 1 on a module board 5 with underfill material 3 spread around the bumps is illustrated in FIG. 3, showing how the topography of the bottom of the CISCSP 1 is accommodated by and supported by the underfill material 3.

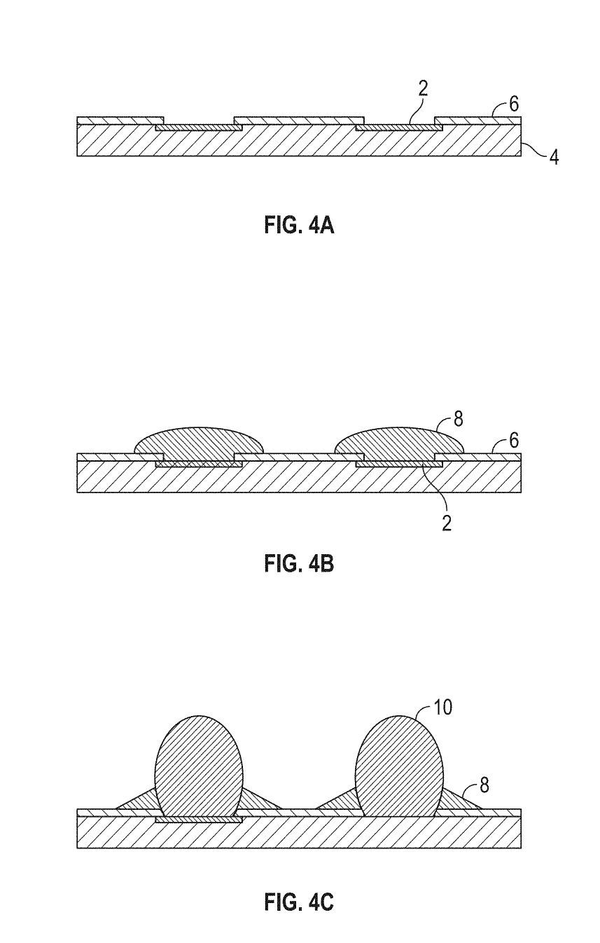

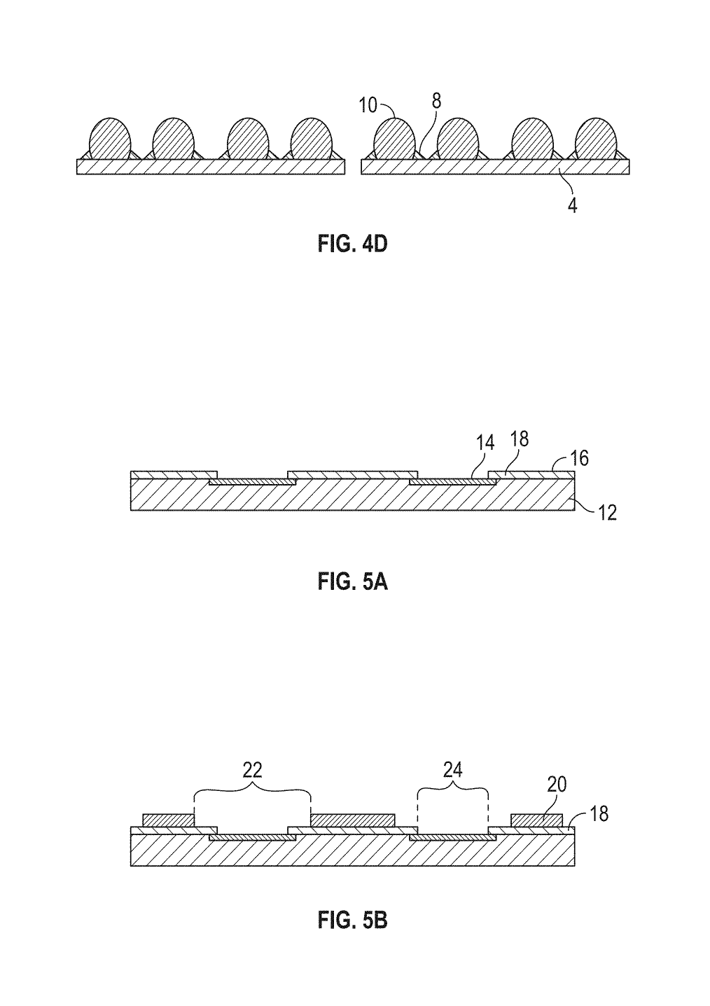

Referring to FIG. 4A-4D, a process flow including the use of polymer collars or solder encapsulation materials is illustrated. In this process, a plurality of pads 2 on a CSP wafer 4 are surrounded by a dielectric layer 6 as illustrated in FIG. 4A. Referring to FIG. 4B, solder encapsulation material 8 is then applied onto the pads 2 and the edges of the dielectric layer 6. Referring to FIG. 4C, balls 10 are then dropped into the solder encapsulation material 8 which then distributes itself and flows around the shape of the balls 10 and the dielectric layer 6 material. Referring to FIG. 4D, the wafer 4 is then singulated into packages by sawing. As illustrated, the maximum height that the solder encapsulation material can reach up the side of a bump from the pad toward the top of the bump is about 50 microns using the technique of FIGS. 4A-D. Data gathered indicates that when this technique is applied to a CISCSP package, limited improvement in board level reliability (BLR) was observed even when the maximum coverage height was used where no underfill material was subsequently applied to the package/module board joint. The BLR testing was done using a test board and using the JEDEC reliability test methods. Because of this, for CISCSP packages, the use of a solder encapsulation material using the process flow illustrated in FIG. 4A-4D with a polymer collar without also using an underfill material can be improved with respect to preventing cracking and reliability issues.

An implementation of a process and structure for enabling the use of CISCSP packages with no underfill material will now be described. Various implementations include the use of solder encapsulation materials as well. While the process and structure is disclosed for use with CISCSP packages, the same processes and structures disclosed herein can be used for wafer level chip scale packages as well.

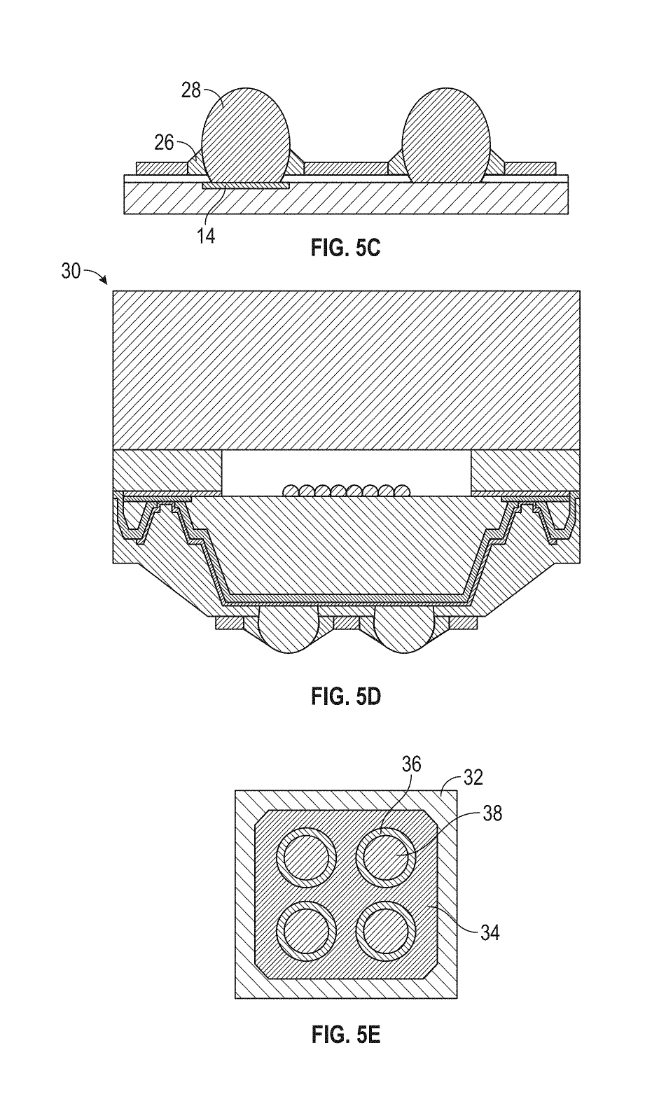

Referring to FIG. 5A-5E, a process flow for forming an implementation of a CISCSP is illustrated. As illustrated in FIG. 5A, the process begins with a wafer 12 with pads 14 on which a first solder mask defined (SMD) layer 16 is applied. In particular implementations, the SMD may be formed of a film and so the SMD layer may be an SMF as illustrated in FIG. 5A-5E. The thickness of the first SMF 18 may be about 30 microns or less in height. Referring to FIG. 5B, a second non solder mask defined film (NSMF) layer is then applied on top of the first SMF 18 which has a thickness which is about 30 microns or larger. The second NSMF 20 may vary in thickness greater or less than about 30 microns and will be equal to or thicker than the thickness of the first SMF. The size of the openings 22 of the second NSMF around the pad will also be larger than the size of the openings 24 in the first SMF material.

As illustrated in FIG. 5C, the solder encapsulant material 26 is then applied to the pads 14. As illustrated, the solder encapsulant 26 is a liquid material and flows outwardly until it encounters the edges of the openings 24 in the first SMF and the edges of the openings 22 in the second NSMF. The balls 28 are then dropped into the openings 24 in the first SMF and the openings 22 in the second NSMF and the package is reflowed. As illustrated, during the drop and reflow process, the solder encapsulant material is cured against the solder bump. Because of the additional film height provided by the second NSMF, the solder encapsulant material height achieved along the side of the bump in various implementations is greater than 50 microns measured from the base of the bump to the top of the bump. In other implementations, the height of the second NSMF may be 30 microns thick. The solder encapsulant material is also constrained by the second NSMF so that it cannot flow off away from the bump during the reflow process and ball drop process.

The resulting wafer is then singulated (typically using a saw process or other wafer singulation process) and the resulting semiconductor package 30 is illustrated in FIG. 5D. A drawing of the bottom of the package showing the bumps is also included in FIG. 5E, which shows the outline of the first SMF material 32, the outline of the second NSMF material 34, and the shape of the solder encapsulant 36 around the bumps 38.

In various implementations of semiconductor packages including CISCSP, the second NSMF material may act like a hard mask or liquid containment boundary (dam) to limit the flow of the solder encapsulant material away from the bump. In various implementations, the first SMF material can be applied as solder mask defined (SMD) meaning that it contains the openings around the pads sized to allow the bumps to properly attach during the reflow process. In various implementations, however, the first SMF material may not be defined to include all or any of the SMD layer, depending upon what additional layers of material are already present on the wafer around the pads (passivation layers, polyimide layers, etc.). The second NSMF material may be applied as non-solder mask defined (NSMD), which does not include portions that are used to form the openings to allow the bump to properly attach to the pad during the reflow process. However, in other implementations, the second NSMF may include some or all of the SMD, depending on the nature of the materials and existing layers present on the wafer.

The material of the first SMF and the second NSMF may be the same material or may be different materials. The materials selected for the first SMF and the second NSMF may be selected from a wide variety of materials including, by non-limiting example, liquid film types, dry film types, photodefinable film materials, screen printable film types and any other material capable of forming a thick film with openings therethrough. The materials may be applied using a wide variety of possible techniques such as, by non-limiting example, spray coating, spin coating, lamination, or UV enhanced application techniques. Any of a wide variety of ball encapsulation materials may be used in various implementations as well, including, by non-limiting example, solder encapsulation materials, polymeric materials, epoxy materials, any of the compounds disclosed in the references previously incorporated by reference herein, and any other materials capable of flowing up or around the shape of the bump during the ball drop and/or reflow process.

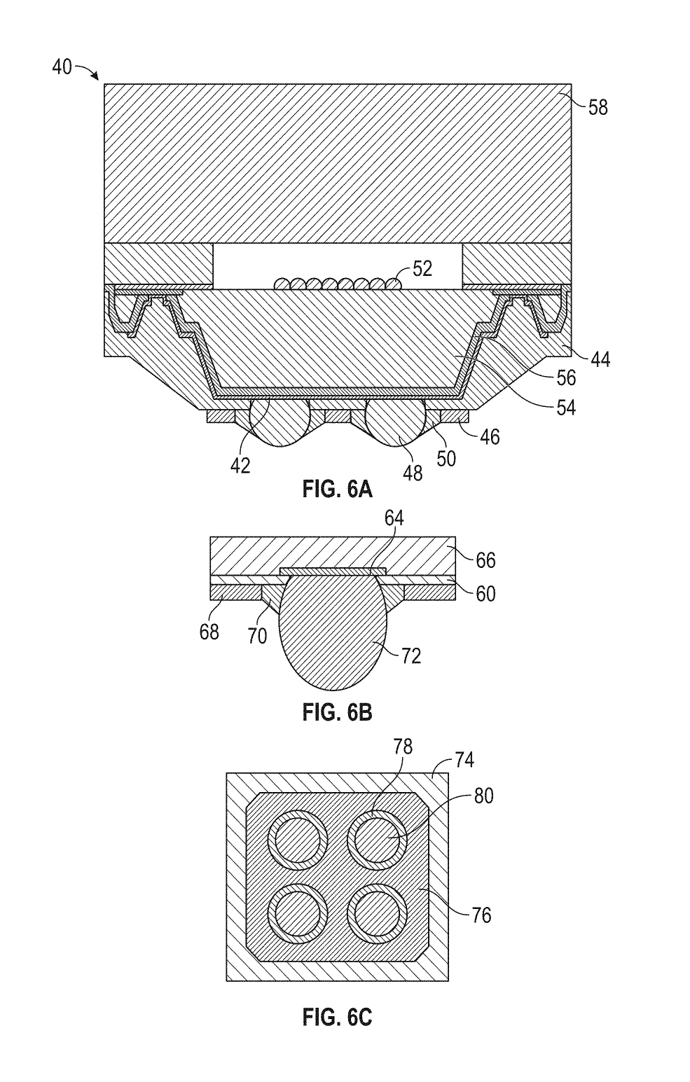

Referring to FIG. 6A, a cross sectional view of a semiconductor package 40 is illustrated. An implementation of a semiconductor package 40 includes a plurality of pads 42 and a first dielectric layer 44 with a plurality of openings through the first dielectric layer. The plurality of openings expose at least a portion of each of the plurality of pads 42. The semiconductor package also includes a second dielectric layer 46 coupled to the first dielectric layer 44. The second dielectric layer 46 may have a thickness greater than a thickness of the first dielectric layer. The second dielectric layer 46 has a plurality of openings corresponding with the plurality of openings in the first dielectric layer 44. As previously described, the semiconductor package includes a plurality of bumps 48 coupled with the plurality of pads 42 into the plurality of openings in the first dielectric layer and in the second dielectric layer. The bump encapsulation material 50 is disposed around the plurality of bumps 48. The bump encapsulation material extends upwardly from the material of the plurality of pads 42 along the sides of the plurality of bumps 38. This implementation of a semiconductor package may be configured to couple with a motherboard using no underfill material between the plurality of bumps and the motherboard. As illustrated, the first SMF layer 44 (1^{st} dielectric layer (DL)) and the second NSMF layer 46 (2^{nd} DL) are used to support the bump reinforcement material 50 (BRM) during the processing and result in a higher level of BRM along the sides of the bump 48.

The use of the second DL/NSMF layer and the ball encapsulation material permits the CISCSP to be bonded to a module board or motherboard without requiring the use of any underfill. The greater height of the ball encapsulation material and/or the additional structural support of the second DL/NSMF material prevent the material of the bump and/or the RDL circuitry from cracking during thermal stressing during operation of the devices. The ability to omit the use of underfill eliminates one or more processing steps along with the cost reduction per package of not having to include the underfill material in the package itself. In various implementations, the ability to eliminate the underfill material occurs while using the same ball encapsulant material as used in CISCSP packages that employ underfill materials. In others, however, other ball encapsulant materials may be different from those used in underfill processes and/or new materials may be enabled by the use of the second DL/NSMF layer. In addition, a high volume of ball encapsulation can be achieved with this technique which correspondingly increases bump strength.

This implementation of a semiconductor package 40 is an image sensor having a plurality of microlenses 52 coupled to the semiconductor die 54. In various implementations, the semiconductor package may also have a dam coupled around a perimeter of the semiconductor die and a transparent/translucent layer coupled to the dam over the semiconductor die. In various implementations, the layer 58 is made of glass. In this way, the CISCSP is formed to allow the image sensor portion of the chip to interact/receive light through the glass.

A close up cross sectional view of an individual bump is illustrated in FIG. 6B, which shows the height difference between the thickness of the second DL 68 and the first DL 60 materials. In this view, the smaller components are more visible such as the first dielectric layer 60 coupled to the semiconductor die 66. In various implementations, the first dielectric layer may be a solder mask defined (SMD) layer as previously described. In some implementations, the SMD layer may include a film. The first dielectric layer 60 has openings to expose the pad 64 on the semiconductor die 66. Coupled over the first dielectric layer 60 is the second dielectric layer 68. The second dielectric layer contains and supports the encapsulation material 70 disposed around the bump 72 as described herein.

Referring to FIG. 6C, a higher magnification view of the structure in FIG. 5 showing a bottom view of the package and the orientation of the openings in the first DL and the second DL relative to the bumps. Specifically, the first dielectric layer 74 can be seen on the outer edge of the drawing. The second dielectric layer 76 is within the boundary of the first dielectric layer 74 surrounding the encapsulation material 78 which is disposed around each of the plurality of bumps 80.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A semiconductor package comprising:
a semiconductor die comprising a plurality of pads and a first dielectric layer with a plurality of openings therethrough that expose at least a portion of each of the plurality of pads;
a second dielectric layer coupled to the first dielectric layer, the second dielectric layer having a plurality of openings corresponding with the plurality of openings in the first dielectric layer, wherein the plurality of openings of the second dielectric layer have a width that is greater than a width of the plurality of openings of the first dielectric layer;
a plurality of bumps coupled with the plurality of pads into the plurality of openings in the first dielectric layer and into the plurality of openings in the second dielectric layer; and
a bump encapsulation material disposed around the plurality of bumps and extending upwardly from the material of the plurality of pads along sides of the plurality of bumps;
wherein the package is configured to couple with a motherboard using no underfill material between the plurality of bumps and the motherboard.

2. The package of claim 1, wherein the second dielectric layer comprises a thickness that is one or equal to and greater than a thickness of the first dielectric layer.

3. The package of claim 1, wherein a material of the first dielectric layer is one of the same as and different from a material of the second dielectric layer.

4. The package of claim 1, wherein the thickness of the second dielectric layer is configured to raise the encapsulation height of a solder encapsulation material to a desired height.

5. The package of claim 1, wherein the thickness of the second dielectric layer is greater than 30 microns.

6. The package of claim 1, where the semiconductor die is an image sensor comprising a plurality of microlenses coupled to the semiconductor die, a dam coupled around a perimeter of the semiconductor die, and a glass layer coupled to the dam over the semiconductor die.

7. The package of claim 2, wherein one of the first dielectric layer and the second dielectric layer are applied using one of spray coating, spin coating, and lamination.

8. A complementary metal oxide semiconductor (CMOS) image sensor chip scale package (CISCSP) comprising:
a semiconductor die comprising a plurality of pads and a first solder mask defined (SMD) layer with a plurality of openings therethrough that expose at least a portion of each of the plurality of pads;
a second non-solder mask defined (NSMD) layer coupled to the first SMD layer, the second NSMD layer having a plurality of openings corresponding with the plurality of openings in the first SMD layer, wherein the plurality of openings of the second NSMD layer have a width that is greater than a width of the plurality of openings of the first SMD layer;
a plurality of bumps coupled with the plurality of pads into the plurality of openings in the first SMD layer and into the plurality of openings in the second NSMD layer; and
a bump encapsulation material disposed around the plurality of bumps and extending upwardly from the material of the plurality of pads along sides of the plurality of bumps.

9. The package of claim 7, wherein a material of the first SMD layer is one of the same as and different from a material of the second NSMD layer.

10. The package of claim 7, wherein the first SMD layer comprises a film.

11. The package of claim 7, wherein the second NSMD layer comprises a film.

12. The package of claim 7, wherein the thickness of the second NSMD layer is configured to raise the encapsulation height of a solder encapsulation material to a desired height.

13. The CISCSP of claim 7, wherein the thickness of the second NSMD layer is greater than 30 microns.

14. The CISCSP of claim 7, further comprising a plurality of microlenses coupled to the semiconductor die, a dam coupled around a perimeter of the semiconductor die, and a glass layer coupled to the dam over the semiconductor die.

15. The CISCSP of claim 7, wherein one of the first dielectric layer and the second dielectric layer are applied using one of spray coating, spin coating, and lamination.

16. A method of forming a complementary metal oxide semiconductor (CMOS) image sensor chip scale package (CISCSP), the method comprising:
providing a semiconductor layer having a plurality of pads thereon;
applying a first dielectric layer to the semiconductor layer;
forming a plurality of openings in the first dielectric layer over the plurality of pads;
applying a second dielectric layer to the semiconductor layer;
forming a plurality of openings in the second dielectric layer corresponding with the openings in the first dielectric layer;
applying a ball encapsulation material to the plurality of pads;
dropping a plurality of balls into the ball encapsulation material;
reflowing the plurality of balls to couple the plurality of balls with the plurality of pads; and
curing the ball encapsulation material along sides of the plurality of balls, the ball encapsulation material height along the sides determined by a thickness of the second dielectric layer;
wherein the thickness of the second dielectric layer is configured to raise a height of the ball encapsulation of a solder encapsulation material to a desired height; and
wherein the thickness of the second dielectric layer is greater than 30 microns.

17. The method of claim 15, wherein a material of the first dielectric layer is one of the same material and a different material from a material of the second dielectric layer.

18. The method of claim 15, wherein the second dielectric layer comprises a thickness that is one of equal to and greater than a thickness of the first dielectric layer.

19. The method of claim 15, further comprising coupling a plurality of microlenses to the first side of the semiconductor layer, coupling a dam around a perimeter of the semiconductor layer, and coupling a glass layer to the dam over the semiconductor layer.

20. The method of claim 16, wherein one of the first dielectric layer and the second dielectric layer are applied using one of spray coating, spin coating, and lamination.
